(19) United States
(12) Patent Application Publication
(10) Pub. No.: US 2013/0168530 A1
(43) Pub. Date: Jul. 4, 2013

(54) MOUNTING APPARATUS FOR FAN MODULE

(71) Applicants: HONG FU JIN PRECISION INDUSTRY (ShenZhen, Shenzhen City (CN); HON HAI PRECISION INDUSTRY CO., LTD., Tu-Cheng (TW)

(72) Inventors: WEN-HU LU, Shenzhen City (CN); PO-WEN CHIU, Tu-Cheng (TW); ZHAN-YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/626,996

(22) Filed: Sep. 26, 2012

(30) Foreign Application Priority Data
Dec. 28, 2011 (CN) 201110446822.9

(51) Int. Cl. H05K 7/14; H05K 7/20

(52) U.S. Cl. 248/678

(57) ABSTRACT

A mounting apparatus for a fan module includes a mounting assembly, a cover, and a control module. The mounting assembly includes a base for receiving the fan module and a mounting member. The base includes a bottom plate. The mounting member includes a body secured to the bottom plate, a latching end extending obliquely from the body, and a latching piece extending from the latching end. The cover is secured to the base. The control module includes a driving member slidably mounted to the base including a latching portion. The latching portion is located between the latching end and the bottom plate. The latching piece extends out of the bottom plate and is adapted to engage with an object. The driving member can slide, to elastically deform the latching end away from the bottom plate, to move the latching piece towards the bottom plate.

### BACKGROUND

1. Technical Field

The present disclosure relates to a mounting apparatus, and particularly to a mounting apparatus for fan module.

2. Description of Related Art

Electronic components in computers, such as central processing units and power supplies, generate a large mount of heat. A fan module is usually provided for the power supply to assist in cooling the electronic components. The fan module is generally mounted in a bracket, and then the bracket is mounted in each computer enclosure by screws, a process requires a screw driver to secure the bracket with screws. Disassembly or reassembly of the fan module is tedious and inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a fan module and a mounting apparatus.

FIG. 2 is an exploded, isometric view of a mounting assembly of the mounting apparatus of FIG. 1.

FIG. 3 is similar to FIG. 2, but viewed from a different aspect.

FIG. 4 is a front view of the mounting assembly of FIG. 2.

FIG. 5 is an assembled view of the mounting apparatus and the fan module of FIG. 1.

FIG. 6 is similar to FIG. 5, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

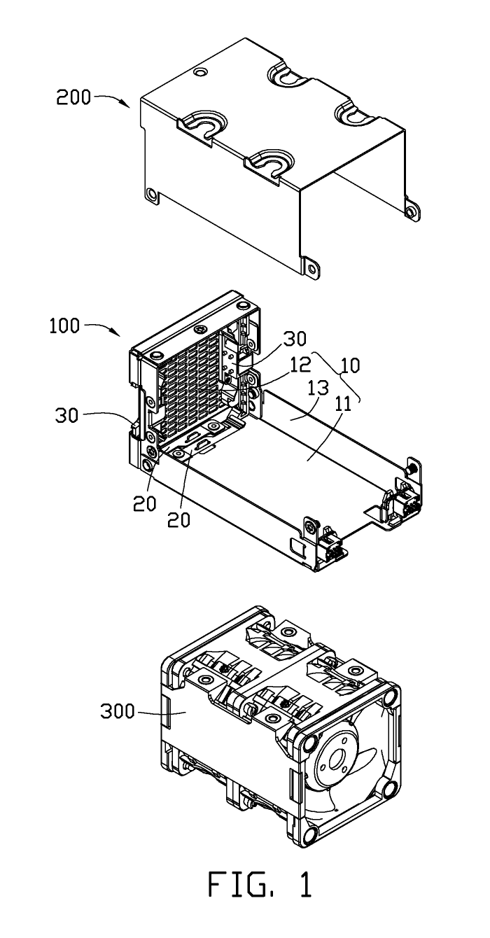

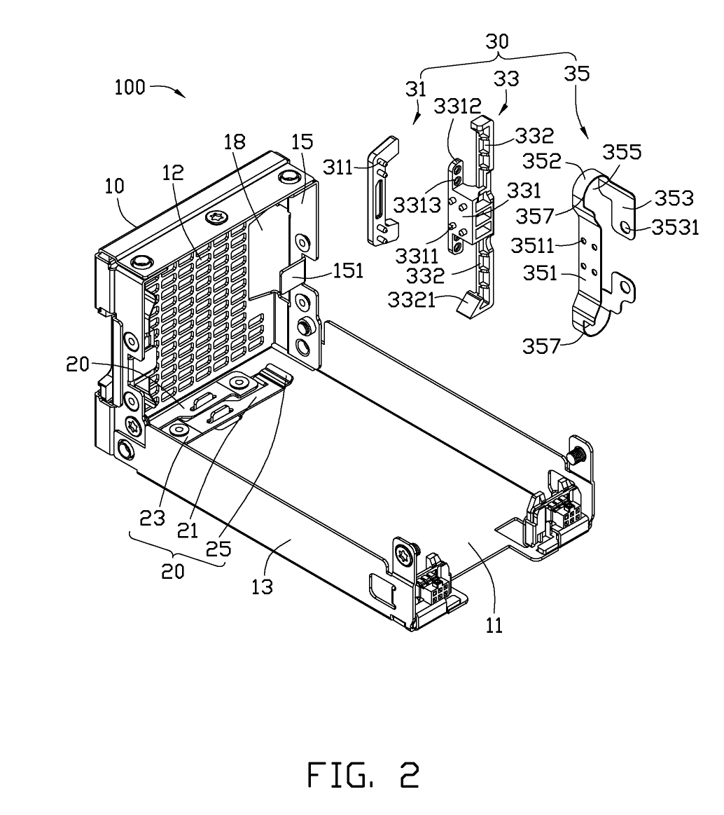

Referring to FIG. 1 and FIG. 2, an embodiment of a mounting apparatus for receiving a fan module 300 is shown. The mounting apparatus comprises a mounting assembly 100 and a cover 200.

The mounting assembly 100 comprises a base 10, two mounting members 20, and a control module 30.

The base 10 comprises a bottom plate 11, a side plate 12, and two mounting plates 13. The two mounting plates 13 are opposite to each other. In one embodiment, the bottom plate 11 is substantially perpendicular to the side plate 12 and the two mounting plates 13. Two flanges 15 extend perpendicularly from opposite side edges of the side plate 12. Each of the two flanges 15 is secured to each of the two mounting plates 13. A limiting piece 151 extends from the each of the two flanges 15. In one embodiment, the two flanges 15 are substantially parallel to the two mounting plates 13, and the limiting piece 151 is substantially parallel to the side plate 12. The side plate 12 defines two cutouts 18 at opposite sides.

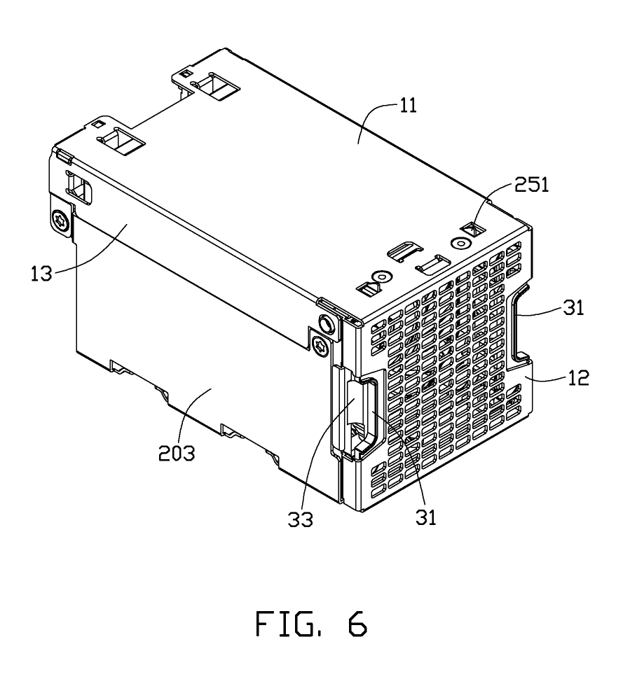

Each of the two mounting members 20 comprises a body 21, a mounting end 23, and a latching end 25. The latching end 25 and the mounting end 23 are positioned in two opposite ends of the body 21. The mounting end 23 is secured to the bottom plate 11. The body 21 abuts against the bottom plate 11. The latching end 25 extends obliquely from the body 21. An obtuse angle is defined between the body 21 and the latching end 25. A latching piece 251 (shown in FIG. 6) extends from a bottom surface of the latching end 25. The latching piece 251 extends out of the bottom plate 11 to be inserted into a hole of a chassis (not shown), to secure the mounting apparatus to the chassis.

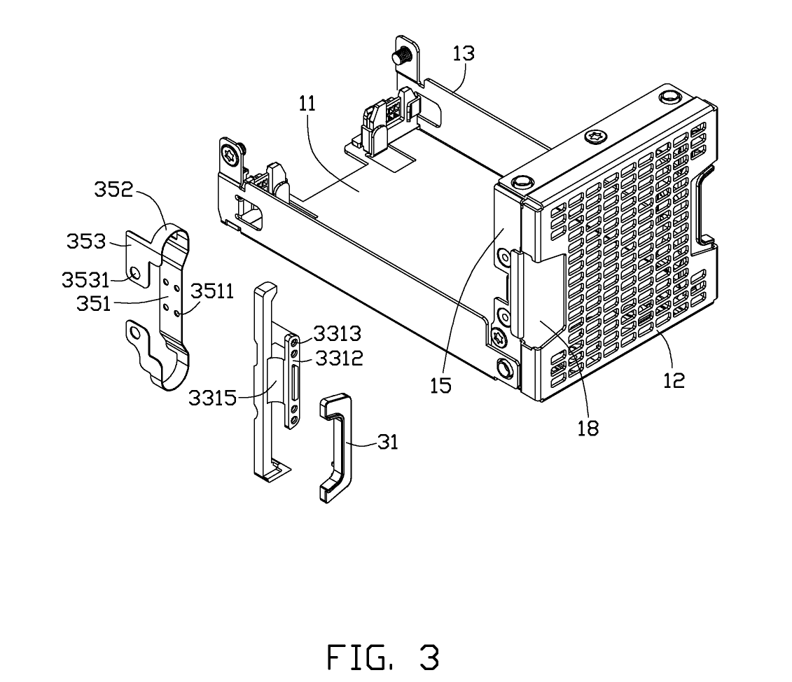

The control module 30 comprises a hand 31, a driving member 33, and a resilient member 35. A plurality of limiting posts 311 extends from a side of the hand 31. The driving member 33 comprises a mounting portion 331 and two positioning portions 332 extending from two opposite ends of the mounting portion 331. A plurality of positioning posts 3311 extends from a first side of the mounting portion 331 away from the two positioning portions 332. A second side of the mounting portion 331, opposite to the first side, defines a recess portion 3315 (shown in FIG. 3). The recess portion 3315 is configured for fingers to operate the hand 31 conveniently. Two mounting pieces 3312 extend from two opposite edges of the mounting portion 331. Each of the two mounting pieces 3312 defines two limiting holes 3313. Each of the two limiting holes 3313 corresponds to each of the plurality of limiting posts 311. A latching portion 3321 extends from an end of one of the two positioning potions 332. In one embodiment, the latching portion 3321 is substantially at an angle of 45 degrees from the vertical.

The resilient member 35 comprises an installation piece 351, two resilient pieces 352, and two locking pieces 353. The two resilient pieces 352 extend from two opposite edges of the installation piece 351. The installation piece 351 defines a plurality of installation holes 3511. Each of the two locking pieces 353 extends from each of the two resilient pieces 352 and is substantially parallel to the installation piece 351. In one embodiment, each of the two resilient pieces 352 is curved. Each of the two resilient pieces 352 defines a cutout 355 which forms a resisting edge 357. Each of the two locking pieces 353 defines a locking hole 3531.

The cover 200 comprises two sidewalls 203 (shown as in FIG. 6).

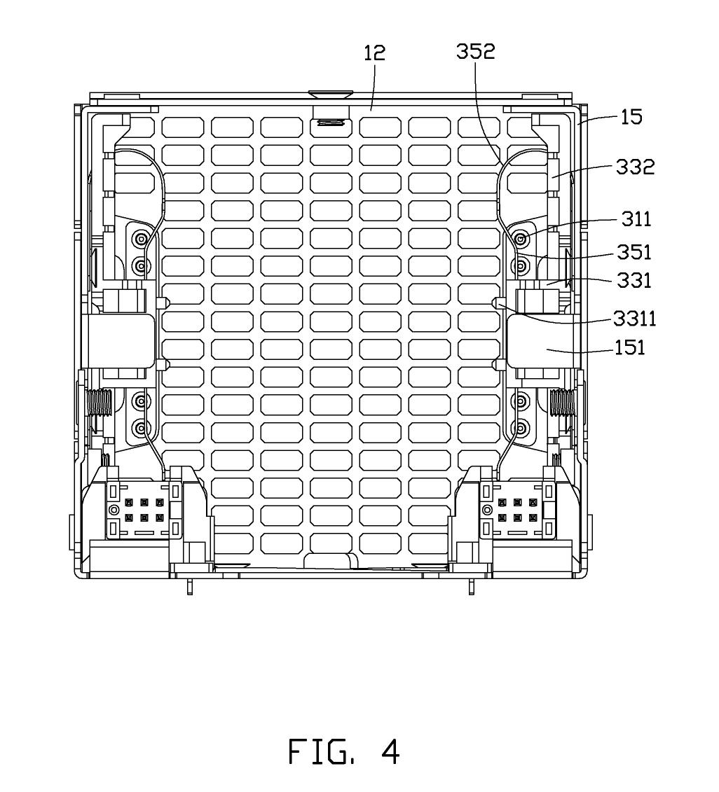

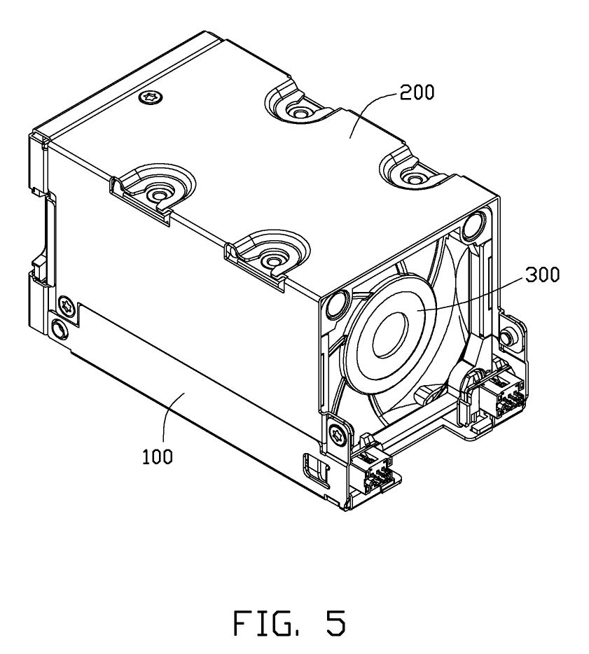

FIGS. 4-6 show that, in assembly, the driving member 33 is moved a position adjacent to the cutout 355 of the resilient member 35. Each of the two locking pieces 353 is pulled away from the installation piece 351, elastically deforming the two resilient pieces 352. The driving member 33 is moved to position the mounting portion 331 between the installation piece 351 and the locking pieces 353, until each of the plurality of positioning post 3311 is aligned with each of the plurality of installation holes 3511. The two resilient pieces 352 rebound to engage each of the plurality of positioning posts 3311 in each of the plurality of installation holes 3511. In this position, each of the two positioning portions 332 is received in each of the two cutouts 355 and is abutting the resisting edge 357. The hand 31 is moved to a position adjacent to the driving member 33, and each of the plurality of limiting posts 311 is aligned with one of the two limiting holes 3313. The hand 31 is pressed towards each of the two mounting pieces 3312, until each of the plurality of limiting posts 311 engages in each of the two limiting holes 3313. Each of the plurality of limiting posts 311 is located between the installation piece 351 and the two locking pieces 353 and is abutting the installation piece 351. Thus, the control module 30 is completely assembled.

The limiting piece 151 is pulled away from the side plate 12. The control module 30 is moved between the limiting piece 151 and the side plate 12. The two locking pieces 353 are secured to the two flanges 15. The latching portion 3321 is engaged between the bottom plate 11 and the latching end 25. The limiting piece 151 rebounds to engage the control module 30 between the side plate 12 and the limiting piece 151. Thus, the control module 30 is secured to the base 10. The fan module 300 is placed in the base 10. The cover 200 can then be secured to the base 10 to cover the fan module 300, and the sidewalls 203 are secured to the two mounting plates 13.

Each of the two mounting members 20 is movable between a locked position and an unlocked position. When each of the two mounting members 20 is in the locked position, the two latching pieces 251 extend out of the bottom plate 11 and are engaged with the chassis, to prevent the mounting apparatus from moving out of the chassis. When each of the two mounting members 20 is in the unlocked position, the two latching pieces 251 are back within the base 10 and disengaged from the chassis, and the mounting apparatus can be moved relative to the chassis.

The control module 30 is operable to move the two mounting members 20 between the locked position and the unlocked position. When each of the two mounting members 20 is in the locked position, the two hands 31 are moved towards each other through the two cutouts 18 to deform the two resilient pieces 352 away from the two locking pieces 353. The two driving members 33 move towards each other together with the hands 31, and the latching portion 3321 raises up the latching end 25 and elastically deforms the body 21 away from the bottom plate 11. Thus, the latching piece 251 is back within the base 10, and each of the two mounting members 20 is moved from the locked position to the unlocked position. The two hands 31 are released, whereupon the two resilient pieces 352 rebound to move the driving member 33 and the hands 31 away from the latching end 25. In this position, the body 21 rebounds to extend the latching piece 251 out of the bottom plate 11. Thus, each of the two mounting members 20 is moved from the unlocked position to the locked position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for a fan module, comprising:
a mounting assembly comprising a base and a mounting member; the base being configured for receiving the fan module and comprising a bottom plate; the mounting member comprising a body secured to the bottom plate, a latching end extending obliquely from the body, and a latching piece extending from the latching end;
a cover secured to the base; and
a control module comprising a driving member slidably mounted to the base and comprising a latching portion;
wherein the latching portion is located between the latching end and the bottom plate; the latching piece extends out of the bottom plate and is configure to engage with an object; the driving member is slidable to elastically deform the latching end away from the bottom plate, and to move the latching piece towards the bottom plate.

2. The mounting apparatus of claim 1, wherein the body abuts the bottom plate, and an obtuse angle is defined between the latching end and the body.

3. The mounting apparatus of claim 1, wherein the latching portion is substantially at an angle of 45 degrees relative to the bottom plate.

4. The mounting apparatus of claim 1, wherein the base further comprises a flange, a limiting piece extending from the flange, and a side plate substantially perpendicular to the bottom plate; the flange is substantially perpendicular to the side plate; the limiting piece is substantially parallel to the side plate; and the control module is secured between the limiting piece and the side plate.

5. The mounting apparatus of claim 4, wherein the control module comprises a resilient member secured to the flange and a hand secured to the driving member; the driving member is secured to the resilient member; and the resilient member is elastically deformable to slide the driving member away from or towards the mounting member.

6. The mounting apparatus of claim 5, wherein the resilient member comprises an installation piece secured to the driving member, a locking piece secured to the flange, and a resilient piece connecting the installation piece and the locking piece.

7. The mounting apparatus of claim 6, wherein the locking piece is substantially parallel to the installation piece, and the resilient piece is curved.

8. The mounting apparatus of claim 6, wherein the driving member comprises a mounting portion and a positioning portion extending from the mounting portion, and the mounting portion is secured to the installation piece; the resilient piece defines a cutout and a resisting edge defined around the cutout, the positioning portion is received in the cutout, and the positioning portion and the limiting piece abut the resisting edge.

9. The mounting apparatus of claim 8, wherein the driving member further comprises a mounting piece extending from the mounting portion; the mounting piece defines a limiting hole, the hand comprises a limiting post, and the limiting post is engaged in the limiting hole; the hand is operable to elastically deform the resilient member relative to the mounting member.

10. The mounting apparatus of claim 9, wherein the limiting post is located between the installation piece and the locking piece and abuts the installation piece.

11. A mounting apparatus for a fan module, comprising:
a mounting assembly comprising a base and a mounting member; the base being configured for receiving the fan module and comprising a bottom plate; the mounting member comprising a body movably mounted to the bottom plate, a latching end extending obliquely from the body, and a latching piece extending from the latching end;
a cover secured to the base; and
a control module comprising a driving member slidably mounted to the base and comprising a latching portion;
wherein the latching portion is located between the latching end and the bottom plate; the driving member is slidable relative to the mounting member to rotate the latching end between a locked position and an unlocked position; when the latching end is in the locked position, the latching piece extends under the bottom plate and engages the base with an object; when the latching end is in the unlocked position, the latching piece is above the bottom plate.

12. The mounting apparatus of claim 11, wherein the body abuts the bottom plate, and an obtuse angle is defined between the latching end and the body.

13. The mounting apparatus of claim 11, wherein the latching portion is substantially at an angle of 45 degrees relative to the bottom plate.

14. The mounting apparatus of claim 11, wherein the base further comprises a flange, a limiting piece extending from the flange, and a side plate substantially perpendicular to the bottom plate; the flange is substantially perpendicular to the side plate; the limiting piece is substantially parallel to the side plate; and the control module is secured between the limiting piece and the side plate.

15. The mounting apparatus of claim 14, wherein the control module comprises a resilient member secured to the flange and a hand secured to the driving member; the driving member is secured to the resilient member; and the resilient member is elastically deformable to slide the driving member away from or towards the mounting member.

16. The mounting apparatus of claim 15, wherein the resilient member comprises an installation piece secured to the driving member, a locking piece secured to the flange, and a resilient piece connecting the installation piece and the locking piece.

17. The mounting apparatus of claim 16, wherein the locking piece is substantially parallel to the installation piece, and the resilient piece is curved.

18. The mounting apparatus of claim 16, wherein the driving member comprises a mounting portion and a positioning portion extending from the mounting portion, and the mounting portion is secured to the installation piece; the resilient piece defines a cutout and a resisting edge defined around the cutout, the positioning portion is received in the cutout, and the positioning portion and the limiting piece abut the resisting edge.

19. The mounting apparatus of claim 18, wherein the driving member further comprises a mounting piece extending from the mounting portion; the mounting piece defines a limiting hole, the hand comprises a limiting post, and the limiting post is engaged in the limiting hole; the hand is operable to elastically deform the resilient member relative to the mounting member.

20. The mounting apparatus of claim 19, wherein the limiting post is located between the installation piece and the locking piece and abuts the installation piece.
